(19) United States
(12) Patent Application Publication
(10) Pub. No.: US 2006/0218468 A1
(43) Pub. Date: Sep. 28, 2006

(54) Memory initialization device, memory initialization method, and error correction device

(75) Inventors: Yukikazu Kuramoto, Osaka (JP); Daigo Senoo, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/371,248

(22) Filed: Mar. 9, 2006

(30) Foreign Application Priority Data
Mar. 9, 2005 (JP) 2005-065913

(51) Int. Cl. G11C 29/00

(52) U.S. Cl. 714/763

(57) ABSTRACT

In a case where a data missing area has occurred when a memory portion in a SYNC information set buffer memory is being overwritten with SYNC information sets (error correction data), an initialization DMA unit obtains the starting address and the end address in the data missing area from an address setting DMA device, and writes a specific value indicating that main data contains errors at each address in the data missing area between the starting address and the end address for initialization of the data missing area. Therefore, even in the case of the occurrence of the data missing area in the memory in which the error correction data indicating the presence/absence of errors in the main data is written over existing data and stored, the errors in the main data are corrected properly in accordance with data output from the memory.

### CROSS-REFERENCES TO RELATED APPLICATIONS

This Non-provisional application claims priority under 35 U.S.C. §119(a) on Patent Application No. 2005-065913 filed in Japan on Mar. 9, 2005, the entire contents of which are hereby incorporated by reference. The entire contents of Patent Application No. 2006-46308 filed in Japan on Feb. 23, 2006 are also incorporated by reference.

### BACKGROUND OF THE INVENTION

The present invention relates to a memory initialization device for initializing a memory for storing error correction data that is used in correcting errors in transmitted main data, a method for initializing the memory, and an error correction device using the memory initialization device.

A main-data error correction device has conventionally been provided with a buffer memory for storing and accumulating error correction data. Such an error correction device includes a buffer memory for storing main data read from, e.g., a Blu-ray Disc and a buffer memory for storing error correction data read from the Blu-ray Disc, so that in a case, e.g., where the main data stored in the buffer memory is error data due to noise having entered the main data during the read operation of the main data from the Blu-ray Disc, the error-containing main data can be corrected properly. That is, the error correction device is configured so that errors in the main data are corrected using the error correction data stored in the buffer memory.

FIG. 4 shows the configuration of data read from a Blu-ray Disc, for example. In the configuration shown in FIG. 4, a SYNC information (synchronous data) set is at the head, followed by LDC (Long Distance Code) data sets and BIS (Burst Indicator Subcode) data sets that are alternately arranged in the horizontal direction, thereby forming a single frame, and vertically placed 31 frames form a single sector and then a plurality of such sectors are arranged. The LDC data sets are error coded data sets each containing main data, parity check data for correcting errors in the main data, and the like. Each SYNC information set and the BIS data set immediately after the SYNC information set are error coded dada sets each containing information indicating whether or not the LDC data set existing between the SYNC information set and the BIS data set contains any errors. The respective values of a given number of BIS data sets are added together, which enables those BIS data sets to have the parity check function of detecting errors therein. The SYNC information sets, however, do not have such parity check function.

As indicated by arrows shown in FIG. 4, the data sets in a single frame, i.e., the SYNC information set and the alternately and horizontally arranged LDC data sets and the BIS data sets in this order, are transmitted to the conventional error correction device, and this is repeated for transmission of each frame. The error correction device successively stores only the SYNC information sets of the transmitted data sets in one of the two internal buffer memories thereof, while successively storing the LDC data sets and the BIS data sets in the other buffer memory. The reason why only the SYNC information sets are stored in the one buffer memory is that once these SYNC information sets have been used to correct errors in the LDC data sets, they will no longer be used and become unnecessary.

FIG. 5 schematically shows the configuration of the buffer memory for storing only the SYNC information sets. The buffer memory is divided into two portions: a memory portion A and a memory portion B. In the buffer memory with this structure, the SYNC information sets are stored (written) as follows. First, before the writing of the SYNC information sets, the determination as to which of the two memory portions A and B will be used is made beforehand. Then, the starting address in the determined memory portion (for example, A) is established and the SYNC information sets are written in sequence starting from this starting address. When the writing of the SYNC information set at the last address in the memory portion A has been completed, then the remaining SYNC information sets are sequentially written into the other memory portion (for example, B) starting from the starting address in the other memory portion B. In the state in which the SYNC information sets are being written into the other memory portion B, errors in the main data sets are corrected using the SYNC information sets stored in the one memory portion A and the BIS data sets stored in the other buffer memory. When the writing of the SYNC information set at the last address in the other memory portion B has been complete, the remaining SYNC information sets are again written into the memory portion A over the already written SYNC information sets, whereby the already written SYNC information sets are lost. The Japanese Laid-Open Publication No. 2000-181785, for example, discloses this kind of technique, in which a buffer memory is divided into a plurality of unit memories composed of memory portions having a certain capacity and the use conditions of these unit memories are managed.

However, the conventional error correction device described above has the following drawback, which will be discussed in detail below.

When data is read from a Blu-ray Disc, the data transfer rate and the data capture timing must be synchronized, because the peripheral speed of the optical disc differs between the central portion thereof and the peripheral portion thereof. The device for playing back the Blu-ray Disc is therefore provided with such a synchronous circuit. When it is detected that synchronization provided by this synchronous circuit is lost, the writing of the SYNC information sets stored in the sector that contains the SYNC information set currently being written is stopped, and the SYNC information sets in the next sector are correctly captured starting from the beginning in synchronization with the data transfer rate and written into the buffer memory.

However, as shown in FIG. 4, for example, when it is found at a point C that the synchronization is lost, a jump to the beginning of the next sector takes place (which will be hereinafter referred to as a “sector jump”). As a result, the SYNC information sets in the diagonally shaded area in FIG. 4 are not written into the buffer memory and the SYNC information sets contained in the next sector are successively written into the buffer memory from the beginning. In the buffer memory shown in FIG. 5, the dashed arrow indicates a data missing area in which the SYNC information sets were not written due to the sector jump, while the solid arrow after the dashed arrow indicates the SYNC information sets that were written after the sector jump. Since the buffer memory shown in FIG. 5 is overwritten with the SYNC information sets, the already written old SYNC information sets remain in the dashed arrow area in which the new SYNC information sets were not written.

The old SYNC information sets reaming as described above cause the following disadvantage. This disadvantage will be described with reference to FIG. 6. FIG. 6 shows the internal states of, e.g., the memory A in the buffer memory, in which the SYNC information sets have been written. In the state 1, a sector jump has not yet occurred and the numerous number of written SYNC information sets all indicate that the main data sets do not contain any errors, and have a value of “8′h00”, for example. The state 2 shows a state in which the overwriting of the memory A with the SYNC information sets has been started again from the starting address and then, during the overwriting process, a sector jump has occurred. In the diagonally shaded area in the state 2, since the new SYNC information sets have not been written over the previously written old SYNC information sets as described above, the previously written old SYNC information sets remain. Therefore, even if at least part of the SYNC information sets that should have been newly written in the diagonally shaded data-missing area indicates that the corresponding main data set or sets contain errors, those errors will not be corrected although they should be corrected, because the old SYNC information sets (indicating that the main data sets do not contain any errors) remain as shown in the state 2′. In cases where a sector jump has occurred during write operation for a sector, the LDC data sets and the BIS data sets existing in the portion of that sector from the address at which the sector jump has occurred to the last address are also not written in the other buffer memory, causing loss of these data sets. However, these LDC data sets and BIS data sets have parity check function and the like and thus correction (reproduction) of the original data sets is possible. On the other hand, the SYNC information sets, which do not have such parity check function, are not capable of self-correction. Therefore, in a process for correcting errors in the LDC data sets existing between the old SYNC information sets and the immediately following BIS data sets, even if these BIS data sets indicate that the LDC data sets contain errors, the errors in the LDC data sets are not corrected, because the old SYNC information sets indicate that the LDC data sets contain no errors. As a result, the LDC data sets having erroneous values are output without being corrected, thereby causing decrease in the quality of the transferred data.

### SUMMARY OF THE INVENTION

It is therefore an object of the present invention to provide an error correction device in which even if, in a memory for storing, by an overwrite operation, error correction data for use in correcting errors in main data, loss of the error correction data occurs due to a sector jump such as described above or the like, the errors in the main data are reliably corrected.

In order to achieve the object, according to the present invention, even in cases where a plurality of error correction data sets are not written and thus lost, data in each address in the data missing area is overwritten with a specific value indicating that the corresponding main data contains errors, so that the errors in the main data are corrected without fail.

Specifically, an inventive memory initialization device includes: a memory, in which existing data is successively overwritten with error correction data for use in determining whether or not main data contains errors for storage of the error correction data, and a specific value providing circuit for filling a data missing area in the memory with a specific value indicating that the main data contains errors, wherein in the data missing area, the existing data is not overwritten with the error correction data due to an interruption of the overwriting of the memory with the error correction data.

In one embodiment of the inventive memory initialization device, the specific value providing circuit is an initialization DMA unit which writes, in an entire -storage area in the memory, the specific value indicating that the main data contains errors, before the overwriting of the memory with the error correction data is started.

In another embodiment, the memory initialization device further includes an address setting DMA unit for setting addresses in the memory at which the error correction data is to be written, wherein the specific value providing circuit is an initialization DMA unit which obtains a starting address and an end address in the data missing area from the address setting DMA unit and, based on the starting address and the end address, writes in the data missing area the specific value indicating that the main data contains errors, thereby initializing the data missing area.

In another embodiment, the memory is divided into a plurality of memory portions, which are overwritten in turn with the error correction data.

In another embodiment, the error correction data and the specific value written in the memory are output to an error correction/determination device for determining whether or not there are any errors in the main data and correcting the errors.

In another embodiment, the memory successively receives the error correction data of data sets read from an optical disc, and the data missing area in the memory is created due to a sector jump which is a jump made from a sector to a next sector in the optical disk during the reading of the data sets from the optical disc.

An inventive error correction device includes: the memory initialization device, and an error correction/determination processing section for receiving data output from the memory disposed in the memory initialization device, and determining whether or not there are any errors in the main data or correcting the errors in accordance with the output data.

In one embodiment of the error correction device, the memory disposed in the memory initialization device is divided into a plurality of memory portions, which are overwritten in turn with the error correction data; and with one of the plurality of memory portions being overwritten with the error correction data, the error correction/determination processing section receives output data from a different one of the memory portions and corrects the errors in the main data in accordance with this output data.

An inventive memory initialization method for initializing a memory in which existing data is successively overwritten with error correction data for use in determining whether or not main data contains errors for storage of the error correction data includes: the initialization step of initializing the memory by writing, in an entire storage area in the memory, a specific value indicating that the main data contains errors, before the overwriting of the memory with the error correction data is started; and the overwriting step of successively overwriting the initialized memory with the error correction data.

Another inventive memory initialization method for initializing a memory in which existing data is successively overwritten with error correction data for use in determining whether or not main data contains errors for storage of the error correction data includes: the overwriting step of successively overwriting the memory with the error correction data; the address obtaining process of obtaining, when a data missing area is created by an interruption of the overwriting of the memory with the error correction data, a starting address and an end address in the data missing area, wherein in the data missing area the existing data is not overwritten with the error correction data; and the initialization step of initializing only the data missing area in the memory by writing a specific value indicating that the main data contains errors, in the data missing area in the memory in accordance with the starting address and the end address.

In one embodiment of the inventive memory initialization method, the memory is divided into a plurality of memory portions; and in the overwriting step, a process is repeated in which an entire storage area in one of the memory portions is successively overwritten with the error correction data for storage of the error correction data, and thereafter an entire storage area in a different one of the memory portions is successively overwritten with the error correction data for storage of the error correction data.

In another embodiment, the error correction data and the specific value written-in the memory are output to an error correction/determination device for determining whether or not there are any errors in the main data and correcting the errors.

In another embodiment of the inventive memory initialization device, the error correction data written in the memory is data that is not capable of correcting errors in the error correction data.

In another embodiment of the inventive memory initialization device, the error correction data written in the memory is SYNC information.

According to the present invention, even in cases where the memory is not Loverwritten with new error correction data indicating whether or not there are any errors in main data due to a sector jump or the like and a data missing area, in which the new error correction data is not present, is thereby created in the memory, the data missing area is filled with data indicating that there are errors in the main data, which allows the errors in the main data to be corrected reliably.

### BRIEF DESCRIPTION OF THE DRAWINGS

FIG. 1 shows the configuration of an error correction device according to a first embodiment of the present invention.

FIG. 2 schematically shows the entire configuration of a memory initialization device in the error correction device.

FIG. 3 schematically shows the entire configuration of a memory initialization device according to a second embodiment of the present invention.

FIG. 4 shows the configuration of data read from a Blu-ray Disc.

FIG. 5 is a view for explaining how, in a memory which is overwritten with error correction data for storage of the error correction data, a data missing area is created when a sector jump has occurred.

FIG. 6 is a view for explaining why error correction is not performed in a conventional error correction device, when a sector jump has occurred.

### DETAILED DESCRIPTION OF THE INVENTION

Hereinafter, the preferred embodiments of the present invention will be described with reference to the accompanying drawings.

### First Embodiment

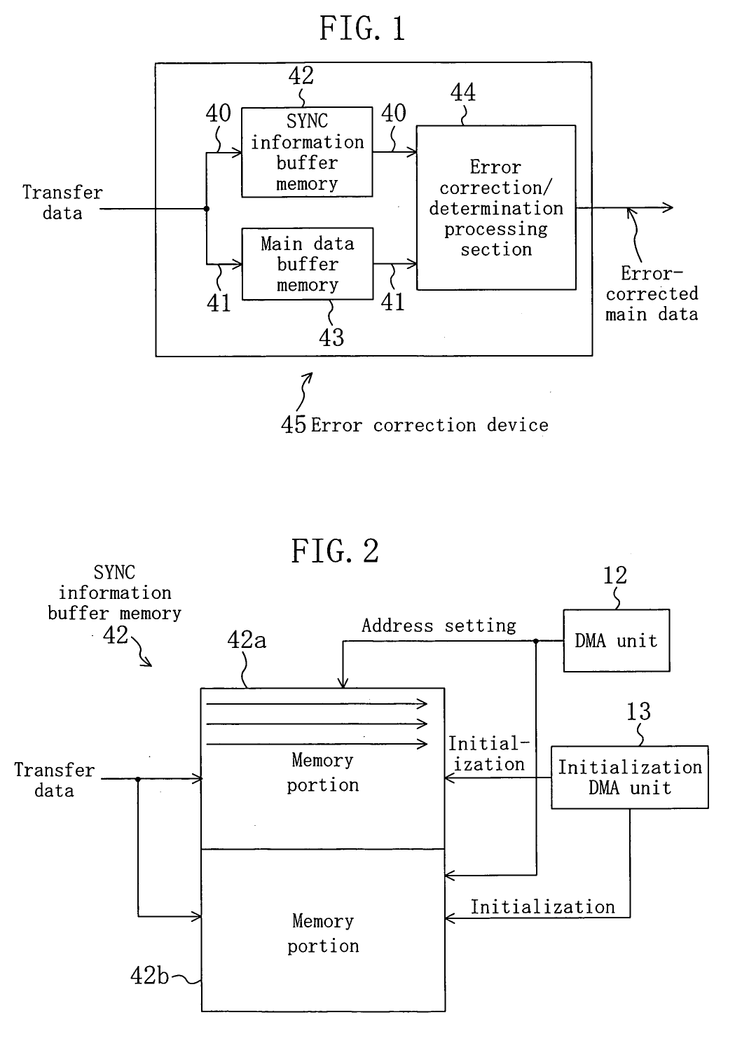

With reference to FIG. 1, an error correction device according to a first embodiment of the present invention will be described.

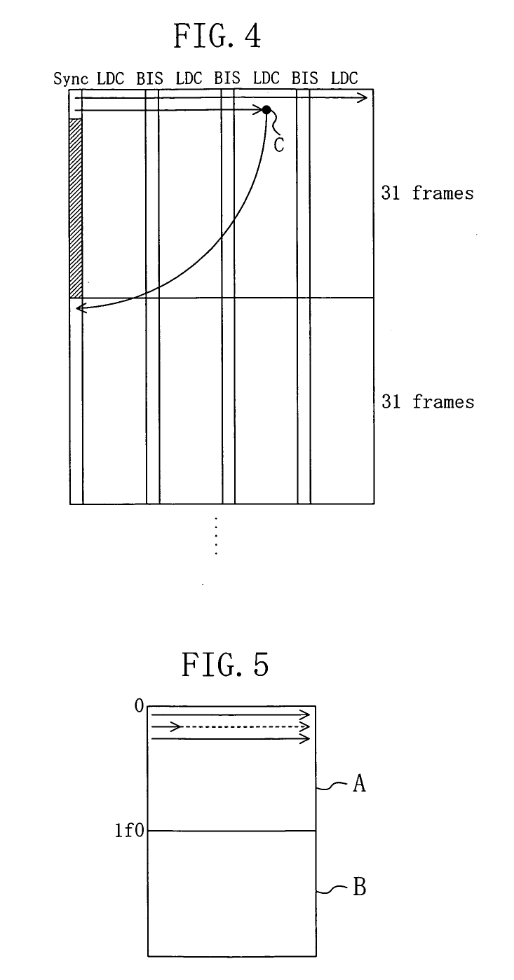

In FIG. 1, the reference numeral 45 refers to the error correction device. The error correction device 45 includes a SYNC information buffer memory 42, a main data buffer memory 43, and an error correction/determination processing section 44. The error correction device 45 receives transfer data transferred from outside. The transfer data is data read from a Blu-ray Disc, for example. As shown in FIG. 4, a SYNC information set, and the following LDC data sets and BIS data sets that are alternately arranged in the horizontal direction form a single frame, and continuously arranged 31 frames form a single sector, and a plurality of such frames are successively transferred one by one to the error correction device 45.

The error correction device 45 divides the received transfer data sets, so that, of the transfer data sets, only the SYNC information sets 40 are output to the SYNC information buffer memory 42, while data 41 composed of the LDC data sets and the BIS data sets is output to the main data buffer memory 43. Therefore, in the SYNC information buffer memory 42, only the SYNC information sets 40 are stored and accumulated, while in the main data buffer memory 43, the LDC data sets and the BIS data sets stored and accumulated.

The error correction/determination processing section 44 receives the SYNC information sets 40 from the SYNC information buffer memory 42, and also receives the LDC data sets and the BIS data sets from the main data buffer memory 43. The error correction/determination processing section 44 then determines whether or not there are any errors in the LDC data sets present between the received SYNC information sets 40 and the BIS data sets existing immediately after the SYNC information sets 40 according to combinations of the values of the SYNC information sets 40 and the values of the BIS data sets, while determining whether or not there are any errors in the respective LDC data set present between two adjacent BIS data sets according to a combination of the values of these two BIS data sets. In this way, the error correction/determination processing section 44 makes the determinations about the presence/absence of errors in the LDC data sets, corrects the errors, and outputs the error-corrected LDC data sets and BIS data sets as the main data sets.

Next, the configuration of a memory initialization device in the error correction device 45 is shown in FIG. 2. In FIG. 2, the memory initialization device includes the SYNC information buffer memory 42, a DMA (Direct Memory Access) device 12, and an initialization DMA unit 13. The SYNC information buffer memory 42 is divided into two portions: a memory portion 42a and a memory portion 42b. When the SYNC information sets 40 are written into the SYNC information buffer memory 42, the DMA unit (address setting DMA unit) 12 makes address setting in such a manner that the SYNC information sets 40 are sequentially written in the entire storage area in one of the two memory portions 42a and 42b and thereafter the remaining SYNC information sets 40 are successively written in the entire storage area in the other memory portion, while the DMA unit 12 sets addresses at which the SYNC information sets 40 are to be written and outputs the addresses to either the memory portion 42a or 42b in the SYNC information buffer memory 42. Also, in a case where a sector jump has occurred during the writing of a SYNC information set 40 stored in a sector, the DMA unit 12, upon receipt of a signal indicating that sector jump, sets the address at which the first SYNC information set 40 in the next sector should be written, as the address from which writing of the SYNC information sets 40 should be started again. Furthermore, before the writing of the SYNC information sets 40 is started from the starting address in either the memory portion 42a or 42b, the initialization DMA unit (specific value providing circuit) 13 initializes, to a specific value, data at each address in the entire storage area in either the memory portion 42a or 42b in which the writing of the SYNC information sets 40 is to be performed. The specific value indicates that there are errors in the corresponding main data set (the LDC data set) and an example of the specific value will be described later.

Next, operation of the memory initialization device will be described. First, normal operation which is performed when no sector jump occurs will be discussed.

The operation described below is performed in a situation in which after the completion of writing of the SYNC information set 40 at the end address in the one memory portion 42a in the SYNC information buffer memory 42, the writing operation has been shifted to the other memory portion 42b and the writing of the SYNC information sets 40 into the other memory portion 42b has been completed from the starting address to the end address.

In this situation, the initialization DMA unit 13 writes the specific value at each address in the entire area in the memory portion 42a so as to initialize the entire area in the memory portion 42a (an initialization process). The specific value is a value indicating that there are errors in the corresponding LDC data set, and is, e.g., such a value that makes the lowest two bits of the total of the specific values written in the entire area be “11”.

Subsequently, the DMA unit 12 sets the starting address in the initialized memory portion 42a and then successively overwrites the memory portion 42a with the SYNC information sets starting from the starting address (an overwriting process). During this overwriting process, the error correction/determination processing section 44 receives the SYNC information sets that have been newly written in the entire area in the other memory portion 42b, and then, based on combinations of the values of these SYNC information sets and the values of the corresponding BIS data sets read from the main data buffer memory 43, determines whether or not there are any errors in the LDC data sets existing between these SYNC information sets and the BIS data sets. If there are any errors in the LDC data sets, the error correction/determination processing section 44 corrects them.

Thereafter, when the writing of the SYNC information set at the end address in the memory portion 42a has been completed, the initialization DMA unit 13 writes the specific value at each address in the entire area in the other memory portion 42b so as to initialize the entire storage area in the memory portion 42b.

Then, the DMA unit 12 sets the starting address in the initialized memory portion 42b and successively overwrites the memory portion 42b with the SYNC information sets starting from the starting address (an overwriting process). During this overwriting process, the error correction/determination processing section 44 receives the SYNC information sets that have been newly written in the entire area in the one memory portion 42a, and then, based on combinations of the values of these SYNC information sets and the values of the corresponding BIS data sets read from the main data buffer memory 43, determines whether or not there are any errors in the LDC data sets existing between these SYNC information sets and the BIS data sets. If there are any errors in the LDC data sets, the error correction/determination processing section 44 corrects them.

When the writing of the SYNC information set at the end address in the memory portion 42b has been completed, the initialization DMA unit 13 writes the specific value at each address in the entire storage area in the one memory portion 42a to initialize the entire storage area in the memory portion 42a. The subsequent processes are performed as described above; the DMA unit 12 sets the starting address in the initialized memory portion 42a and successively overwrites the memory portion 42a with the SYNC information sets starting from the starting address, while the error correction/determination processing section 44 corrects errors in the LDC data sets.

Now, a description will be made of operation which is performed when a sector jump has occurred.

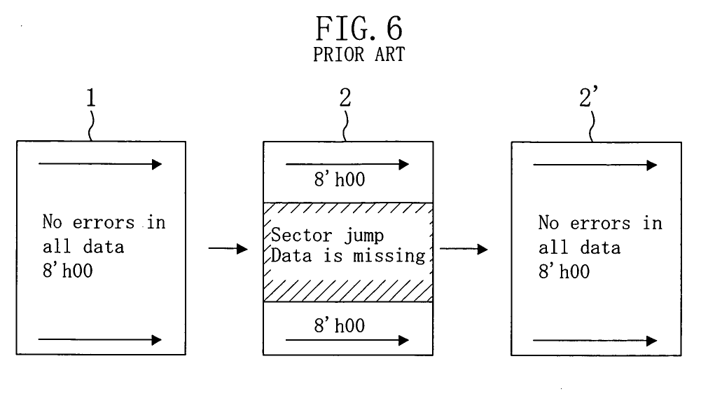

For example, suppose a case in which a sector jump has occurred when the one memory portion 42a in the SYNC information buffer memory 42 is being overwritten with the SYNC information sets, with errors in the LDC data sets being corrected using the SYNC information sets in the other memory portion 42b. In this case, as shown in the state 2 in FIG. 6, writing of the new SYNC information sets is not performed and a diagonally shaded data-missing area is produced. However, before the writing of the SYNC information sets into the memory portion 42a is started from the starting address, the initialization DMA unit 13 has written the specific value at each address in the entire storage area in the memory portion 42a. Therefore, when the error correction/determination processing section 44 determines, after the start of the writing of the SYNC information sets into the other memory portion 42b, whether or not there are any errors in the LDC data sets in accordance with the SYNC information sets stored in the memory portion 42a, it is determined, using the specific value, i.e., the initial value, that the LDC data sets contain errors in the diagonally shaded data-missing area shown in FIG. 6, which has not been overwritten with the new SYNC information sets. Consequently, the errors in the LDC data sets are properly corrected.

As described above, in this embodiment, before each of the memory portions 42a and 42b in the SYNC information buffer memory 42 is overwritten with the SYNC information sets, the entire storage area therein is overwritten with the specific value indicating that the corresponding LDC data set contains errors so that the entire storage area is initialized. Therefore, even if a sector jump has occurred, errors in the LDC data sets can be properly corrected by the error correction/determination processing section 44.

In this embodiment, the SYNC information buffer memory 42 is divided into two portions: the memory portion 42a and the memory portion 42b. Nevertheless, the present invention is not limited the memory in which the number of divisions is two, but a memory which is not divided into a plurality of portions or a memory having three or more divided portions may be used.

### Second Embodiment

Next, a second embodiment of the present invention will be described.

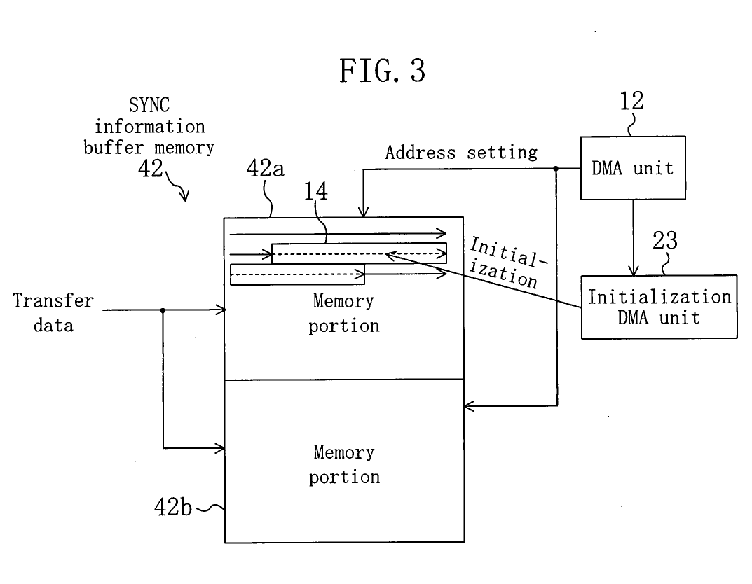

FIG. 3 schematically shows the configuration of a memory initialization device according to this embodiment. The entire configuration of the memory initialization device shown in FIG. 3 is the same as that of the memory initialization device shown in FIG. 2, and they are different only in the configuration and operation of an initialization DMA unit 23.

The initialization DMA unit 13 shown in FIG. 1 initializes, to the specific value, the entire storage area in each of the memory portions 42a and 42b in the SYNC information buffer memory 42. On the other hand, the initialization DMA unit 23 of this embodiment shown in FIG. 3 initializes, only in the case of occurrence of a sector jump, only a data missing area created due to the absence of new SYNC information sets written into that area.

To be more specific, suppose a case, for example, where a sector jump has occurred when the memory portion 42a in the SYNC information buffer memory 42 is being overwritten with SYNC information sets, with errors in LDC data sets being corrected using SYNC information sets in the other memory portion 42b. In this case, a data missing area 14, which has not been overwritten with the new SYNC information sets, is created in the memory portion 42a as indicated by dashed arrows shown in FIG. 3. In this embodiment, the initialization DMA unit 23 obtains from the DMA unit 12 the address (starting address) in the memory portion 42a at which the sector jump has occurred and the address (end address) at which the first SYNC information set in the next sector should be written (an address obtaining process), and fills each address in the data missing area between the starting address and the end address with the specific value for initialization of the data missing area (an initialization process). The filling of the data missing area with the specific value can be easily performed within the time interval existing after the overwriting of the memory portion 42a with the first SYNC information set after the sector jump and until transmission of the SYNC information set in the next frame to the memory portion 42a, because this time interval is the time period required for transmission of the LDC data sets and the BIS data sets contained in the previous frame and is thus sufficiently long for this specific value filling process.

As described above, in this embodiment, even in a case where a sector jump has occurred when either the memory portion 42a or 42b in the SYNC information buffer memory 42 is being overwritten with the SYNC information sets, only the data missing area created by the sector jump, in which no new SYNC information sets have been written, is initialized by filling the data missing area with the specific value. Therefore, as in the first embodiment, even if a sector jump has occurred, errors in the LDC data sets can be properly corrected by the error correction/determination processing section 44.

In this embodiment, the SYNC information buffer memory 42 is divided into two portions: the memory portion 42a and the memory portion 42b. Nevertheless, the present invention is not limited the memory in which the number of divisions is two, but a memory which is not divided into a plurality of portions or a memory having three or more divided portions may be used.

What is claimed is:

1. A memory initialization device comprising:
a memory, in which existing data is successively overwritten with error correction data for use in determining whether or not main data contains errors for storage of the error correction data, and
a specific value providing circuit for filling a data missing area in the memory with a specific value indicating that the main data contains errors, wherein in the data missing area, the existing data is not overwritten with the error correction data due to an interruption of the overwriting of the memory with the error correction data.

2. The memory initialization device of claim 1, wherein the specific value providing circuit is an initialization DMA device which writes, in an entire storage area in the memory, the specific value indicating that the main data contains errors, before the overwriting of the memory with the error correction data is started.

3. The memory initialization device of claim 1, further comprising an address setting DMA device for setting addresses in the memory at which the error correction data is to be written,
wherein the specific value providing circuit is an initialization DMA device which obtains a starting address and an end address in the data missing area from the address setting DMA device and, based on the starting address and the end address, writes in the data missing area the specific value indicating that the main data contains errors, thereby initializing the data missing area.

4. The memory initialization device of claim 1, wherein the memory is divided into a plurality of memory portions, which are overwritten in turn with the error correction data.

5. The memory initialization device of claim 1, wherein the error correction data and the specific value written in the memory are output to an error correction/determination device for determining whether or not there are any errors in the main data and correcting the errors.

6. The memory initialization device of claim 1, wherein the memory successively receives the error correction data of data sets read from an optical disc, and
the data missing area in the memory is created due to a sector jump which is a jump made from a sector to a next sector in the optical disk during the reading of the data sets from the optical disc.

7. An error correction device comprising:
the memory initialization device of claim 1, and
an error correction/determination processing section for receiving data output from the memory disposed in the memory initialization device, and determining whether or not there are any errors in the main data or correcting the errors in accordance with the output data.

8. The error correction device of claim 7, wherein the memory disposed in the memory initialization device is divided into a plurality of memory portions, which are overwritten in turn with the error correction data; and
with one of the plurality of memory portions being overwritten with the error correction data, the error correction/determination processing section receives output data from a different one of the memory portions and corrects the errors in the main data in accordance with this output data.

9. A memory initialization method for initializing a memory in which existing data is successively overwritten with error correction data for use in determining whether or not main data contains errors for storage of the error correction data, the method comprising:
the initialization step of initializing the memory by writing, in an entire storage area in the memory, a specific value indicating that the main data contains errors, before the overwriting of the memory with the error correction data is started; and
the overwriting step of successively overwriting the initialized memory with the error correction data.

10. A memory initialization method for initializing a memory in which existing data is successively overwritten with error correction data for use in determining whether or not main data contains errors for storage of the error correction data, the method comprising:
the overwriting step of successively overwriting the memory with the error correction data;
the address obtaining process of obtaining, when a data missing area is created by an interruption of the overwriting of the memory with the error correction data, a starting address and an end address in the data missing area, wherein in the data missing area the existing data is not overwritten with the error correction data; and
the initialization step of initializing only the data missing area in the memory by writing a specific value indicating that the main data contains errors, in the data missing area in the memory in accordance with the starting address and the end address.

11. The memory initialization method of claim 9, wherein the memory is divided into a plurality of memory portions; and
in the overwriting step, a process is repeated in which an entire storage area in one of the memory portions is successively overwritten with the error correction data for storage of the error correction data, and thereafter an entire storage area in a different one of the memory portions is successively overwritten with the error correction data for storage of the -error correction data.

12. The memory initialization method of claim 9, wherein the error correction data and the specific value written in the memory are output to an error correction/determination device for determining whether or not there are any errors in the main data and correcting the errors.

13. The memory initialization device of claim 1, wherein the error correction data written in the memory is data that is not capable of correcting errors in the error correction data.

14. The memory initialization device of claim 13, wherein the error correction data written in the memory is SYNC information.
